(19) United States
(12) Patent Application Publication
(10) Pub. No.: US 2012/0001143 A1
(43) Pub. Date: Jan. 5, 2012

(54) Switchable Junction with Intrinsic Diode

(76) Inventors: Dmitri Borisovich Strukov, Menlo Park, CA (US); R. Stanley Williams, Portola Valley, CA (US)

(21) Appl. No.: 13/255,158

(22) PCT Filed: Mar. 27, 2009
(86) PCT No.: PCT/US09/38682

§ 371 Date: Sep. 7, 2011

(51) Int. Cl. H01L 45/00

(52) U.S. Cl. 257/2; 257/E45.003

(57) ABSTRACT

A switchable junction (600) with an intrinsic diode includes a first electrode (635) and second electrode (640). A first memristive matrix (605) forms an electrical interface (625) with the first electrode (635) which has a programmable conductance. A semiconductor matrix (615) is electrical contact with the first memristive matrix (605) and forms a rectifying diode interface (630) with the second electrode (640).

### BACKGROUND

Nanoscale electronics promise a number of advantages including significantly reduced features sizes and the potential for self-assembly and for other relatively inexpensive, non-photolithography-based fabrication methods. Nanowire crossbar arrays can be used to form a variety of electronic circuits and devices, including ultra-high density nonvolatile memory. Junction elements can be interposed between nanowires at intersections where two nanowires overlay each other. These junction elements can be programmed to maintain two or more conduction states. For example, the junction elements may have a first low resistance state and a second higher resistance state. Data can be encoded into these junction elements by selectively setting the state of the junction elements within the nanowire array. Increasing the robustness and stability of the junction elements can yield significant operational and manufacturing advantages.

### BRIEF DESCRIPTION OF THE DRAWINGS

The accompanying drawings illustrate various embodiments of the principles described herein and are a part of the specification. The illustrated embodiments are merely examples and do not limit the scope of the claims.

FIG. 1 is a perspective view of one illustrative embodiment of a nanowire crossbar architecture, according to one embodiment of principles described herein.

FIG. 2 is an isometric view of a nanowire crossbar architecture incorporating junction elements, according to one embodiment of principles described herein.

FIGS. 3A and 3B are illustrative diagrams which show current paths through a portion of a crossbar memory array, according to one embodiment of principles described herein.

FIGS. 4A-4C are diagrams of various operational states of an illustrative switchable junction element, according to one embodiment of principles described herein.

FIG. 5 is a diagram of an illustrative switchable junction element which incorporates titanium dioxide and strontium titanate layers to create a stable diode interface at one electrode/semiconductor interface, according to one embodiment of principles described herein.

FIGS. 6A and 6B are diagrams of illustrative embodiments of switchable junction elements, according to one embodiment of principles described herein.

Throughout the drawings, identical reference numbers is designate similar, but not necessarily identical, elements.

### DETAILED DESCRIPTION

Nanoscale electronics promise a number of advantages including significantly reduced features sizes and the potential for self-assembly and for other relatively inexpensive, non-photolithography-based fabrication methods. One particularly promising nanoscale device is a crossbar architecture. Studies of switching in nanometer-scale crossed-wire devices have previously reported that these devices could be reversibly switched and may have an “on-to-off” conductance ratio of ˜10³. These devices have been used to construct crossbar circuits and provide a promising route for the creation of ultra-high density nonvolatile memory. Additionally, the versatility of the crossbar architecture lends itself to the creation of other communication and logic circuitry. For example, new logic families may be constructed entirely from crossbar arrays of switches or from hybrid structures composed of switches and transistors. These devices have the potential to dramatically increase the computing efficiency of CMOS circuits. These crossbar circuits could replace CMOS circuits in some circumstances and enable performance improvements of orders of magnitude without having to further shrink transistors.

The design and manufacture of nanoscale electronic devices present a number of challenges which are being addressed to improve commercial production of nanoscale electronic devices and incorporate these devices into microscale and larger-scale systems, devices, and products.

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

Throughout the specification, a conventional notation for the flow of electrical current is used. Specifically, the direction of a flow of positive charges (“holes”) is from the positive side of a power source to the more negative side of the power source.

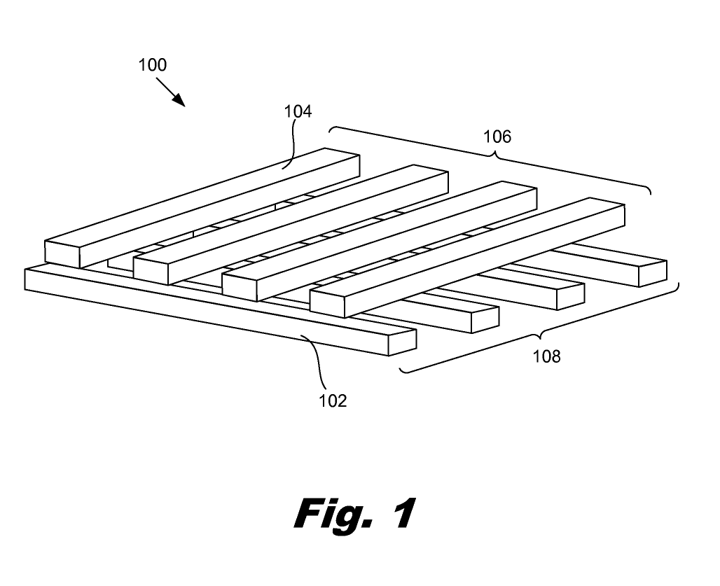

FIG. 1 is an isometric view of an illustrative nanowire crossbar array (100). The crossbar array (100) is composed of a first layer of approximately parallel nanowires (108) that are overlain by a second layer of approximately parallel nanowires (106). The nanowires of the second layer (106) are roughly perpendicular, in orientation, to the nanowires of the first layer (108), although the orientation angle between the layers may vary. The two layers of nanowires form a lattice, or crossbar, each nanowire of the second layer (106) overlying all of the nanowires of the first layer (108) and coming into close contact with each nanowire of the first layer (108) at nanowire intersections that represent the closest contact between two nanowires.

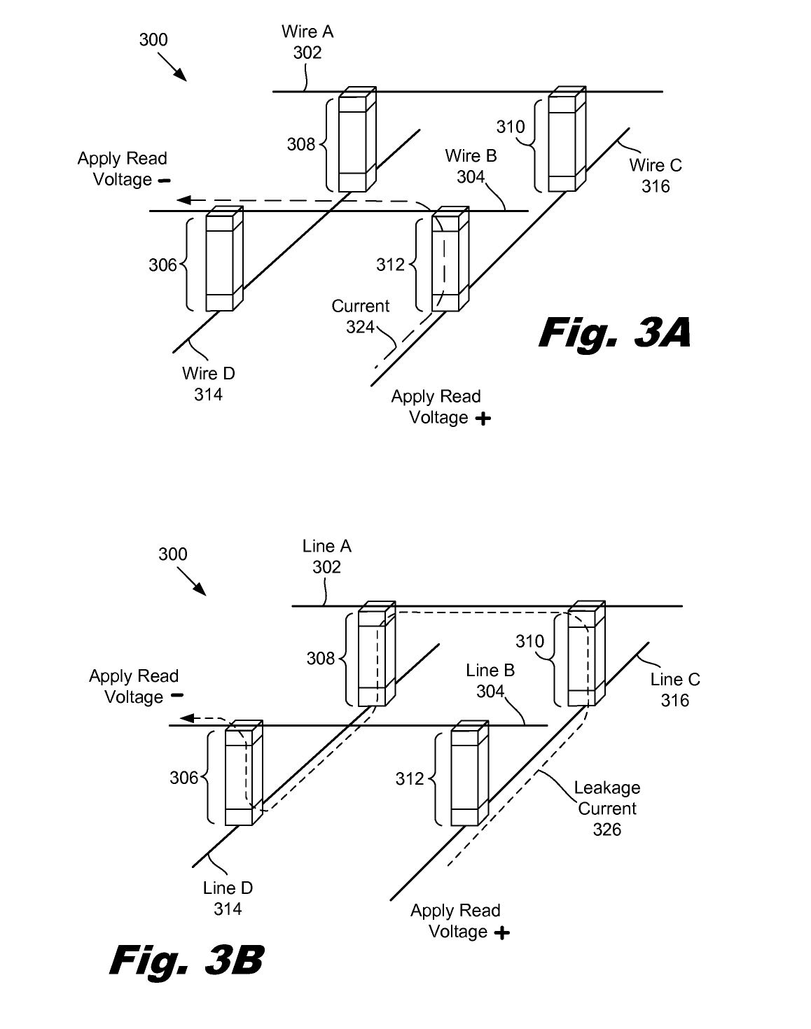

Although individual nanowires (102, 104) in FIG. 3 are shown with rectangular cross sections, nanowires can also have square, circular, elliptical, or more complex cross sections. The nanowires may also have many different widths or diameters and aspect ratios or eccentricities. The term “nanowire crossbar” may refer to crossbars having one or more layers of sub-microscale wires, microscale wires, or wires with larger dimensions, in addition to nanowires.

The layers may be fabricated using a variety of techniques including conventional photolithography as well as mechanical nanoimprinting techniques. Alternatively, nanowires can be chemically synthesized and can be deposited as layers of approximately parallel nanowires in one or more processing steps, including Langmuir-Blodgett processes. Other alternative techniques for fabricating nanowires may also be employed, such as interference lithography. Many different types of conductive and semi-conductive nanowires can be chemically synthesized from metallic and semiconductor substances, from combinations of these types of substances, and from other types of substances. A nanowire crossbar may be connected to microscale address-wire leads or other electronic leads, through a variety of different methods in order to incorporate the nanowires into electrical circuits.

At nanowire intersections, nanoscale electronic components, such as resistors, and other familiar basic electronic components, can be fabricated to interconnect two overlapping nanowires. Any two nanowires connected by a switch is called a “crossbar junction.”

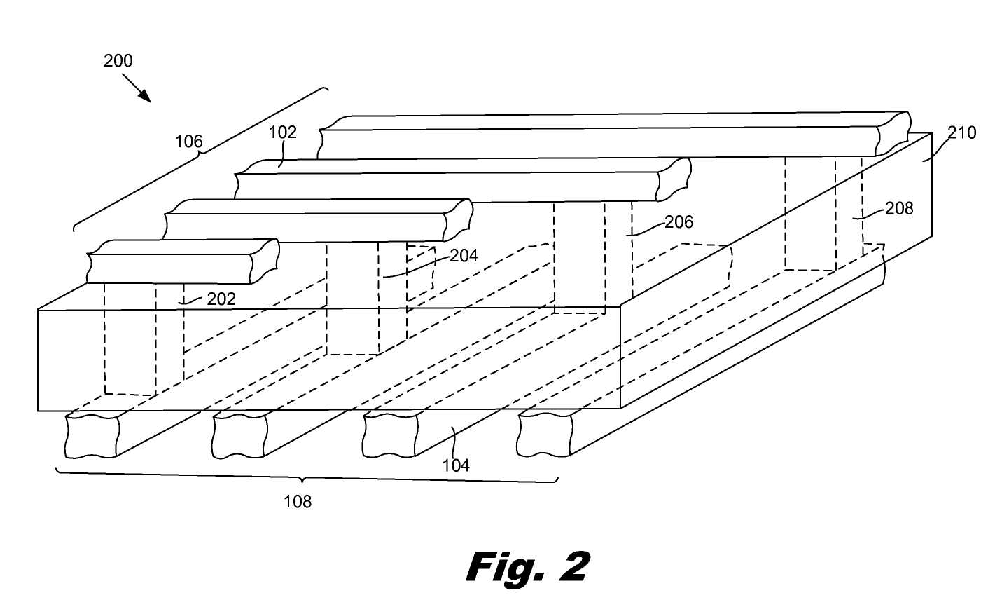

FIG. 2 shows an isometric view of an illustrative nanowire crossbar architecture (200) revealing an intermediate layer (210) disposed between a first layer of approximately parallel nanowires (108) and a second layer of approximately parallel nanowires (106). According to one illustrative embodiment, the intermediate layer (210) may be a dielectric layer. A number of junction elements (202-208) are formed in the intermediate layer at the wire intersection between wires in the top layer (106) and wires in the bottom layer (108). These junction elements (202-208) may perform a variety of functions including providing programmable switching between the nanowires. For purposes of illustration, only a few of the junction elements (202-208) are shown in FIG. 2. As discussed above, it can be desirable in many devices for a junction element to be present at each nanowire intersection. Because every wire in the first layer of nanowires (108) intersects each wire in the second layer of nanowires (106), placing a junction element at each intersection allows for any nanowire in the first layer (108) to be connection to any wire in the second layer (106).

According to one illustrative embodiment, the nanowire crossbar architecture (200) may be used to form a nonvolatile memory array. Each of the junction elements (202-208) may be used to represent one or more bits of data. For example, in the simplest case, a junction element may have two states: a conductive state and a nonconductive state. The conductive state may represent a binary “1” and the nonconductive state may represent a binary “0”, or visa versa. Binary data can be written into the crossbar architecture (200) by changing the conductive state of the junction elements. The binary data can then be retrieved by sensing the state of the junction elements (202-208).

The example above is only one illustrative embodiment of the nanowire crossbar architecture (200). A variety of other configurations could be used. For example, the crossbar architecture (200) can incorporate junction elements which have more than two states. In another example, crossbar architecture can be used to form implication logic structures and crossbar based adaptive circuits such as artificial neural networks.

FIG. 3A is diagram which shows an illustrative crossbar architecture (300). For purposes of illustration, only a portion of the crossbar architecture (300) has been shown and the nanowires (302, 304, 314, 316) have been shown as lines. Nanowires A and B (302, 304) are in an upper layer of nanowires and nanowires C and D (314, 316) are in a lower layer and nanowires. Junctions (306-312) connect the various nanowires at their intersections.

According to one illustrative embodiment, the state of a junction (312) between wire B (304) and wire C (316) can be read by applying a negative (or ground) read voltage to wire B (304) and a positive voltage to wire C (316). Ideally, if a current (324) flows through the junction (312) when the read voltages are applied, the reading circuitry can ascertain that the junction (312) is in its conductive state. If no current, or an insubstantial current, flows through the junction (312), the reading circuitry can ascertain that the junction (312) is in its resistive state.

However, if the junctions (306-310) are purely resistive in nature (i.e. a low resistance is a conductive state and a high resistance is a resistive state) a number of leakage currents can also travel through other paths. These leakage currents can be thought of as “electrical noise” which obscures the desired reading of the junction (312)

FIG. 3B shows a leakage current (326) which travels through an alternative path between wire C (316) and wire B (304). FIG. 3B, the leakage current (326) travels through three junctions (310, 308, 306) and is present on line B (304). As can be imagined, in an array of greater size than that illustrated in FIG. 3B, various leakage currents could travel through a large number of alternative paths and be present on line B (304) when it is sensed by the reading circuitry. These leakage currents can produce a significant amount of undesirable current which obscures the desired reading of the state of the junction (312).

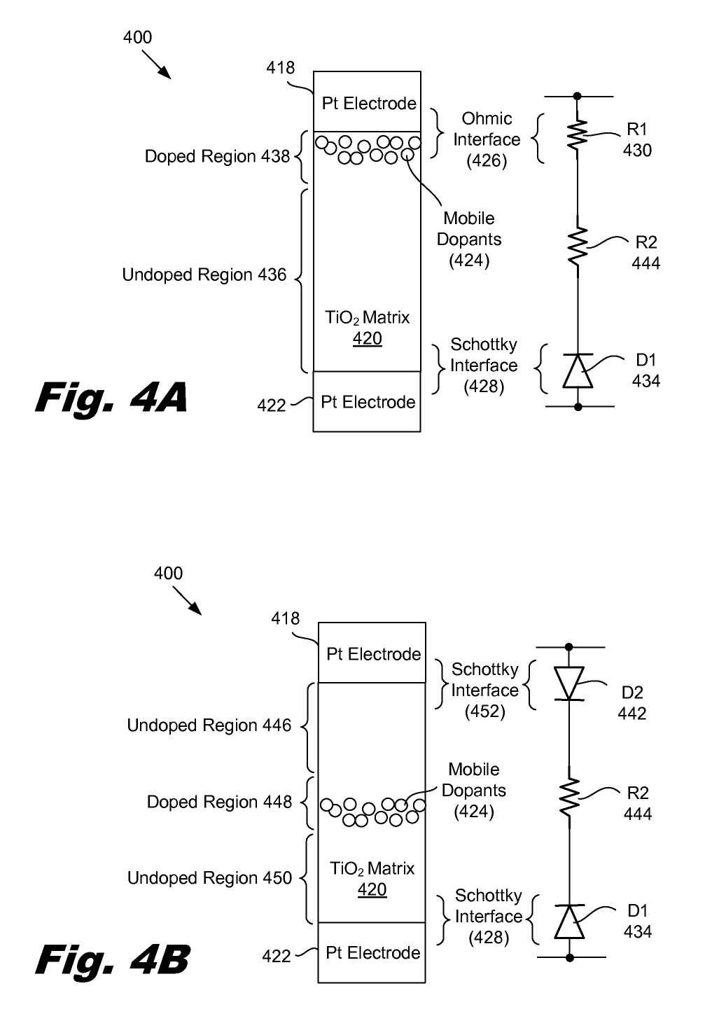

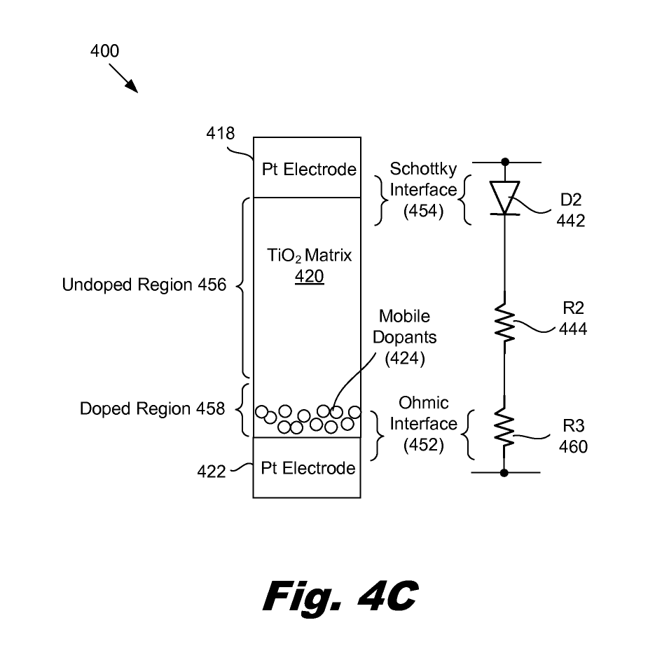

FIG. 4A-4C are diagrams which show one illustrative embodiment of a switchable junction element (400) which can include diode-like behavior which reduces crosstalk. According to one illustrative embodiment, the junction element includes an upper platinum electrode (418) and a lower platinum electrode (422). Typically, the electrodes (418, 422) are the intersecting wires, but the electrodes may be separate elements which are electrically connected to the intersecting wires. The center portion of the junction element (400) may be made up of a memristive matrix material which contains a number of mobile dopants. Under the influence of a relatively high programming voltage, the mobile dopants are moved through the memristive matrix, thereby changing properties of the junction. The mobile dopants remain in position when a lower reading voltage is applied, allowing the state of the junction to remain stable until another programming voltage is applied.

According to one illustrative embodiment, the memristive matrix may be a titanium dioxide (TiO₂) matrix (420) and the mobile dopants (424) may be oxygen vacancies within the titanium dioxide matrix (420). The oxygen vacancy dopants (424) are positively charged and will be attracted to negative charges and repelled by positive charges. Consequently, by applying a negative programming voltage to the upper electrode (418) and a positive programming voltage to the bottom electrode (422), an electrical field of sufficient intensity to move the dopants (424) upward can be achieved. An electrical field of this intensity will not be present within other junctions within a nanowire array because there is only one junction where the wires connected to the upper electrode and lower electrode intersect, namely at the junction (400). Consequently, each of the junctions within a nanowire array can be individually programmed. The mobile dopants (424) drift upward and form a doped region (438) next to the interface between the memristive matrix (420) and the upper electrode (418). The removal of these mobile dopants from the rest of the matrix (420) creates the undoped region (436). Throughout the specification and appended claims, the terms “doped region” and “undoped region” are used to indicate comparative levels of dopants or other impurities which may be present in a material. For example, the term “undoped” does not indicate the total absence of impurities or dopants, but indicates that there are significantly less impurities than in a “doped region.” The titanium dioxide matrix (420) is a semiconductor which exhibits significantly higher conductivities in doped regions and lower conductivities in undoped regions.

As a result of the mobile dopants (424) being grouped at the upper end of the matrix, an Ohmic interface (426) is created at the interface between the upper electrode (418) and the matrix (420). The high electrical conductivity of the upper electrode (418) and the relatively high electrical conductivity of the doped region (438) create a relatively good match in electrical properties at the interface. Consequently, there is a smooth electrical transition between the two materials. This electrical transition is called an Ohmic interface (426). The Ohmic interface (426) is characterized by relatively high electrical conductivity. To the right of the physical diagram of the junction element (400), a corresponding electrical diagram is shown. The Ohmic interface (426) is modeled as a resistor R1 (430). As discussed above, the resistor R1 (430) will have a relatively low resistance due to the low resistance across the interface.

At the interface between the matrix (420) and the lower electrode (422), the conductive metal electrode (422) directly interfaces with the undoped region (436) of the titanium oxide matrix. At this interface, there a large difference in the electrical conductivity and other properties of the adjoining materials. The electrical behavior at this interface is significantly different than the Ohmic interface (426). Instead, the lower interface forms a Schottky-like interface (428). A Schottky interface (428) has a potential barrier formed at a metal-semiconductor interface which has diode-like rectifying characteristics. Schottky interfaces are different than a p-n interface in that it has a much smaller depletion width in the metal. In multilayer thin films, the interface behavior may not be exactly the same as a traditional Schottky barrier. Consequently, various interfaces between the illustrative thin films are described as “Schottky-like.” The corresponding electrical element is modeled as a diode D1 (434). At moderate voltages, the diode D1 (434) allows electrical current to flow in only one direction. In the illustrative embodiment shown in FIG. 4A, the diode D1 (434) only allows current to flow from the lower electrode (422) to the upper electrode (418). By incorporating this diode behavior into each of the junction elements in the crossbar array, a large portion of the cross talk currents can be blocked.

The advantages of this diode behavior can be better understood by returning to FIGS. 3A and 3B. In one embodiment, each of the junction elements (306-312) incorporates this diode behavior. Consequently, current can flow from the lower wires (314, 316) to the upper wires (302, 304) but cannot flow the opposite direction. The reading current of FIG. 3A is not impeded because the flow of the current is upward from wire C (316) to wire B (304). However, the leakage current (326) shown in FIG. 3B is blocked as the leakage current attempts to travel downward through the junction element (308) between line A (302) and line D (314). Other leakage paths within the nanowire array are similarly blocked as they attempt to pass from nanowires in the upper layer of the array to nanowires in the lower layer.

However, the diode behavior breaks down when higher reverse voltages are applied across the junction elements. Diodes and diode-like interfaces have a characteristic reverse voltage at which the barrier to the flow of current breaks down. This characteristic reverse voltage is called the dielectric breakdown voltage. After the dielectric breakdown voltage is exceeded, the interface becomes permanently conductive and current can flow relatively unimpeded through the barrier. In some embodiments, the interface may alternatively be changed by the application of a high reverse voltage such it has a very high electrical resistance. The term “breakdown voltage” as used in the specification and appended claims refers to irreversible chemical changes at an interface rather than reversible breakdown mechanisms such as those used in avalanche or Zener diodes. The dielectric breakdown may occur in both reverse current direction (as described above) and in the forward direction. A dielectric breakdown in the forward direction may occur when the electrical field is relatively small, but the current and heating are great enough to chemically alter the interface.

FIG. 4B illustrates the switchable junction element (400) in a second state. The mobile dopants (424) can be moved away from the top electrode (418) through the application of an appropriate voltage. For example where the mobile dopants (424) are oxygen vacancies, applying a positive voltage to the top electrode (418), a negative voltage to the bottom electrode (422), or a combination of both can produce a motion of the positively charged oxygen vacancies downward toward the center of the matrix (420). This creates an upper undoped region (446), central doped region (448), and a lower undoped region (450). The upper interface then becomes an upper Schottky-like interface (452) which is created by the direct electrical contact between the undoped upper region (446) and the metal electrode (418). The electrical model of the junction is shown to the right of the cross-sectional diagram. The upper diode D2 (442) and the lower diode D1 (434) are in a head-to-head configuration which prevents any substantial current from flowing through the junction (400). The lower diode D1 (434) prevents the downward flow of electrical current and the upper diode D2 (442) prevent the upward flow of electrical current. The resistance R2 (444) represents residual electrical resistances, such as interface resistances and the resistances of materials which make up the interface (418).

The junction state illustrated in FIG. 4B is a nonconductive state. When a reading voltage is applied to the junction no substantial amount of current will pass through the junction. Consequently, by altering the location of the mobile dopants (424), the state of the junction (400) can be altered. The mobile dopants (424) remain in substantially the same distribution until a programming voltage is applied which creates an electrical field sufficient to cause motion of the mobile dopants (424).

FIG. 4C is a diagram of an illustrative third state of the switchable interface element (400). The mobile dopants (424) have been moved to the lower interface between the matrix (420) and the electrode (422). This creates a large upper undoped region (456) and a smaller doped region (458) at the interface to the lower electrode (422). In this configuration, the lower interface becomes an Ohmic interface (452) which is represented by resistor R3 (460) in the electrical model. As discussed above the Ohmic interface (452) is a low resistance interface and the value of the resistor R3 (460) will be minimal. In this state, current can flow from the upper electrode (418) to the lower electrode (422) but cannot travel the reverse direction until the diode breakdown voltage is exceeded or the interface is reconfigured.

In some circumstances, a programming voltage which is applied to induce the motion of the mobile dopants within the memristive matrix may approach a diode breakdown voltage. High programming voltages move the mobile dopants quickly and repeatably into the desired position. For example, the mobility of the dopants within the memristive matrix may be exponentially dependent on the applied voltage. When high programming voltages (>1 MV/cm) are applied, the dopant motion of some dopant species can be extremely rapid and repeatable. Consequently, it can be desirable to use high programming voltages to achieve fast write times and accurate junction states. However, if the programming voltage approaches the dielectric breakdown at a specific interface, the Schottky-like barriers in one or more of the interfaces may breakdown, allowing a surge of current to pass through the junction and nanowires. This can be undesirable for several reasons. First, the excess flow of current increases the power consumption of the device. Second, the surge of current can induce heating in the junctions or nanowires which generates heat. This heat can damage one or more of the components within the nanowire array. For example, the heat may cause chemical changes in the wires or matrix which undesirably alter their properties. Higher heats may cause one or more of the components to melt, creating an electrical short. Consequently, the desire for higher programming voltages can be balanced against the possibility of breaking down the diode-like interfaces within the switchable junction elements.

According to one illustrative embodiment, creating a matrix which incorporates two memristive materials can be advantageous in creating a stable diode interface which has a higher breakdown voltage. This allows the use of the desired programming voltages and rapid writing of data to a crossbar memory array.

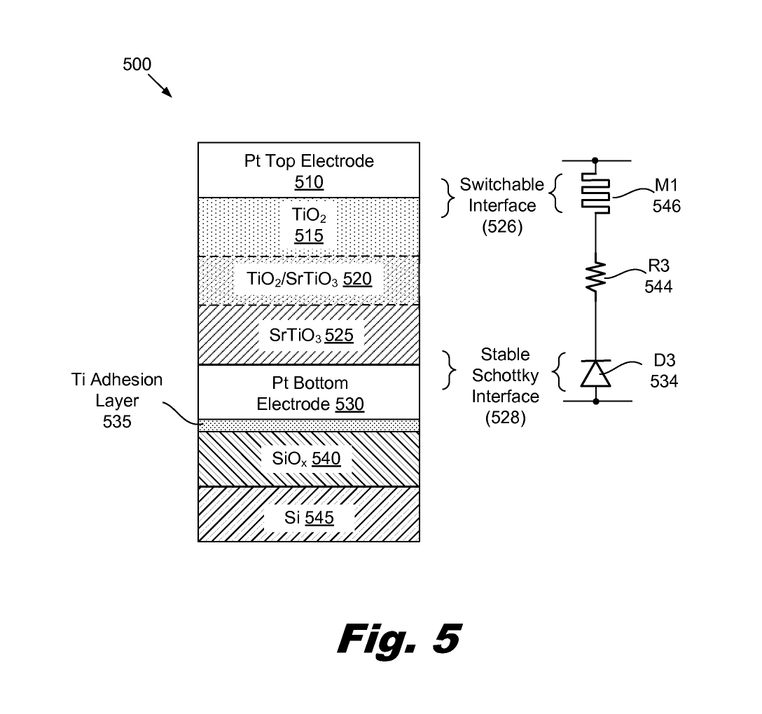

FIG. 5 is a diagram of one illustrative embodiment of a switchable junction (500) which incorporates an intrinsic diode which has a higher resistance to breakdown. According to one illustrative embodiment, the junction is formed on a silicon substrate (545). A dielectric layer of silicon oxide (SiOₓ) (540) insulates the structures from the underlying silicon substrate. A thin titanium adhesion layer (535) promotes bonding of the structure to the silicon oxide layer (540). According to one illustrative embodiment, the titanium adhesion layer (535) may be approximately 5 nanometers thick. A bottom platinum electrode (530) with a thickness of approximately 10 to 500 nanometers is formed over the adhesion layer. As discussed above the platinum electrode (530) may be a section of a nanowire. The electrode material is not limited to platinum, but may be any number of conductive materials or nanostructures which can form a stable Schottky-like interface with an appropriately selected semiconductor material.

A semiconducting or insulating material (called semiconducting for simplicity) is then deposited on top of the bottom platinum electrode (530). According to one illustrative embodiment, the semiconducting material is strontium titanate (SrTiO₃) (525) with a thickness of approximately 2-50 nanometers. The form of strontium titanate used in this embodiment has a permittivity constant k=200 and a breakdown voltage of approximately 2 MV/cm. Above the strontium titanate layer (525) a titanium oxide layer (515) is formed with a thickness of approximately 2 to 100 nanometers. According to one illustrative embodiment, the strontium titanate layer (525) and the titanium oxide layer (515) are formed such that there is significant intermixing between the two materials. This forms a mixed layer (SrTiO₃/TiO₂) (520) which does not exhibit interface behavior. Consequently, the strontium titanate and titanium oxide layers can be modeled electrically as having a minimal electrical resistance at their interface. The titanium dioxide layer (515) has a permittivity constant of approximately k=100 and an electrical breakdown voltage less than 2 MV/cm. A top platinum electrode (510) with a thickness of approximately 10-500 nanometers is formed on top of the titanium dioxide layer (515). The relative vertical position of the strontium titanate and titanium dioxide layers can be different from that shown in the figures. For example, the strontium titanate may be on top of the titanium dioxide memristive layer.

According to one illustrative embodiment, the titanium oxide layer (515) contains mobile dopants, such as oxygen vacancies. As discussed above, the motion of these mobile dopants can change the electrical characteristics of the interface between the titanium oxide and the top electrode (510) between an Ohmic interface and a Schottky-like interface. This forms a switchable interface (526) which can be used to alter the conducting state of the junction element (500). This switchable interface (526) is represented in the electrical model to the right as a memristive element M1 (546). As before, a resistor R3 (544) represents the total static resistance of the interface. The interface between the strontium titanate (525) and electrode (530) forms a stable Schottky-like interface (528) which is represented as diode D3 (534). The description of the Schottky-like interface (528) as being “stable” refers to the substantially higher breakdown voltage of this interface when compared with the switchable interface. Consequently, when a programming voltage is applied, the diode behavior of the stable Schottky-like interface (528) remains intact even after the breakdown of any diode behavior of the titanium oxide/top electrode switching interface.

The stable behavior of the Schottky-like interface (528) provides several advantages. For example, a junction element (500) may be in a conductive state, similar to that shown in FIG. 4A. If it is desirable to reprogram the junction element (500) to the non-conductive state, a positive programming voltage is applied on the top electrode (510). Electrical current is prevented from flowing from the top electrode to the bottom electrode by the stable Schottky-like interface (528). This limits the flow of electrical current through the junction (500). Consequently little power is consumed in reconfiguring the junction element (500). To return the junction (500) to its conductive state, a positive voltage may be applied to the bottom electrode (545).

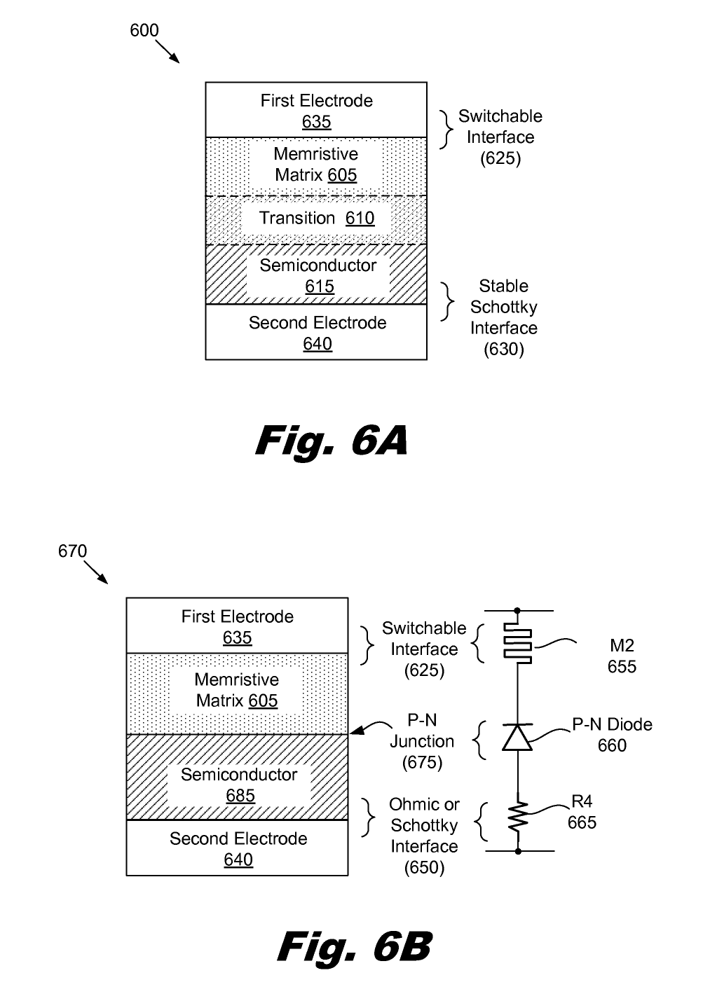

FIG. 6A is an illustrative embodiment of a junction element (600). In general, the junction element (600) will have at least two separated electrodes (635, 640). As discussed above, these electrodes may be formed from a variety of metals or other conductive materials. A memristive matrix (605) is adjacent to the first electrode (635), such that a switchable interface (625) is created. A semiconductor layer (615) is formed adjacent to the second electrode (640), such that a stable Schottky-like interface (630) is created. The stable Schottky-like interface (630) has a higher breakdown voltage than the switchable interface (625). According to one illustrative embodiment, the memristive matrix (605) and the semiconductor layer (615) are joined such that there is no significant interface behavior between them. By way of example and not limitation, this may be accomplished by creating a transition layer (610) which forms a gradual transition between the two materials by intermixing them. In other embodiments, the boundary between the memristive matrix (605) and the semiconductor (615) may be formed by alternative means and may or may not exhibit interface behavior.

For some pairs of oxides, such as titanium dioxide and strontium titanate there is no electrical barrier between the two materials because of their similar bandgaps and electron affinities. However, other oxide pairs may have very different bandgaps and electron affinities. The resulting electrical barrier between at the interface can form what amounts to a p-n junction. This p-n junction can be used as a diode to limit the undesirable crosstalk as discussed above. This can be accomplished by selecting a pair of memristive/semiconducting materials with a large bandgap difference and a large electron affinity difference. Additionally or alternatively, the two materials may have a difference in chemical potential which creates a p-n junction. For example, silicon doped with acceptors and silicon with donors have the same electron affinity and band gap, but may still form a p-n junction because of the chemical potential and resulting charge transfer at the interface.

The titanium oxide/oxygen vacancy memristive matrix illustrated in FIGS. 4A-4C and FIG. 5 is only one illustrative embodiment of a memristive matrix. A number of different types of matrix/dopant combinations could be used. Table 1, below lists a number of illustrative materials and dopants which could be used.

TABLE 1
Illustrative List of Doped Materials,
Undoped Materials, and Mobile Dopants

| Undoped | Doped | Mobile Dopant |
|---|---|---|
| TiO₂ | TiO₂₋ₓ | Oxygen vacancies |
| ZrO₂ | ZrO₂₋ₓ | Oxygen vacancies |
| HfO₂ | HfO₂₋ₓ | Oxygen vacancies |
| SrTiO₂ | SrTiO₂₋ₓ | Oxygen vacancies |
| GaN | GaN₁₋ₓ | Nitrogen vacancies |
| CuCl | CuCl₁₋ₓ | Chlorine vacancies |
| GaN | GaN:S | Sulfide ions |

A number of factors could be taken into account in selecting a matrix and dopant combination. To successfully construct a junction element with the desired rectifying behavior a number of factors could be considered, including: the band gap of the semiconductor matrix, the type and concentration of dopants in the semiconductor, the electrode metal's work function, and other factors.

Similarly, the semiconductor material which makes up the semiconductor layer (615) could be advantageously selected to create the desired stable Schottky-like barrier with the selected electrode material. According to one illustrative embodiment, the semiconductor/memristive combination may be selected using electrical permittivity and electrical breakdown voltage as criteria. For example, the product of the electrical permittivity and electrical breakdown voltage could be used. To form a stable Schottky-like diode at the interface between the semiconductor and an electrode it can be desirable for the semiconductor material to have a higher permittivity and higher breakdown voltage than the memristive matrix. The chart below lists a number of metal oxide semiconductors with their associated dielectric constants and breakdown voltages.

TABLE 2
Physical parameters of various illustrative materials

| | | Theoretical |
|---|---|---|
| | Dielectric | Breakdown voltage |
| Material | constant k | (MV/cm) |
| TiO₂ | 95 | 1.0; 2.5; 4.1 |
| ZrO₂ | 29 | 5.7; 3.3 |
| HfO₂ | 25 | 3.9, 6.7 |
| SrTiO₃ | 200 | 2.2; 2.3 |
| Al₂O₃ | 9 | 13.9; 11.2 |
| La₂O₃ | 30 | 4.0; 5.6; 3.3 |
| Pr₂O₃ | 31 | 3.4; 4.9; 2.8 |

Multiple values are listed in the right column for breakdown voltages. These multiple values represent the different breakdown voltages values for various allotropes of the same material. Table 2 lists only a few of the possible materials which could be used in a switchable junction. Other materials could be used by appropriately selecting the materials with the desired complimenting characteristics.

According to one illustrative embodiment, the memristive matrix may be titanium dioxide, which has a dielectric constant (permittivity) of k=95 and a theoretical breakdown voltage of approximately 1.0 MV/cm. This could be paired with strontium titanate, which has a dielectric constant (permittivity) of k=200 and a theoretical breakdown voltage of above 2.0 MV/cm. Other factors in selecting a semiconductor material may also be considered. For example, the semiconductor material may be chosen such that it is a memristive material which shares the same mobile dopant species as the memristive matrix (605). For example, if titanium oxide is selected as a memristive matrix, strontium titanate may be selected as a semiconductor material. Both titanium oxide and strontium titanate share oxygen vacancies as a mobile dopant species. Another factor may include the ability of the semiconductor material and the memristive matrix to be joined such that there is no substantial interface behavior between the two materials. For example, the two materials may be selected which can be mixed to form a transition layer (610). Additionally or alternatively, two materials with large differences in their bandgaps and electron affinities can be deliberately selected to form a p-n junction between them. This p-n junction may be used to reduce crosstalk within the crossbar structure.

FIG. 6B is a diagram of an illustrative junction element (670) which incorporates two materials which have been deliberately selected to form a p-n junction (675) within the junction element. The memristive matrix (605) and semiconductor (685) may have significant differences in their chemical potential position which results in the creation of the p-n junction (660). This p-n junction (675) is shown as a p-n diode (660) within the junction element (670). The p-n junction (675) can perform a diode function similar to that described above which reduces the crosstalk within a crossbar array.

According to one illustrative embodiment, the semiconductor (685) may be selected and formed such that it either creates an Ohmic interface (650) with the second electrode (640) or Schottky-like interface (630) with a similar rectifying direction to that of p-n junction shown in the FIG. 6A. The Ohmic interface (650) is shown as resistor R4 (665). The memristive matrix (605) creates a switchable interface (635) which is represented by memristor M2 (655) in the electrical model.

In sum, a junction element which is configured to provide both memristive behavior and a stable Schottky-like interface can provide several advantages when incorporated into a nanowire crossbar array. For example, the construction of the junction element may be significantly less complex than other comparable devices. The diode-like behavior of the Schottky-like interface reduces leakage currents. The stability of the device during programming allows for higher programming voltages to be used and quicker write times to be achieved.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A switchable junction (600) with an intrinsic diode comprises:
a first electrode (635);
a second electrode (640);
a first memristive matrix (605) being configured to form an electrical interface (625) with the first electrode (635), the electrical interface (625) having a programmable conductance; and
a semiconductor matrix (615) in electrical contact with the first memristive matrix (605); the semiconductor matrix (615) being configured to form a rectifying diode interface (630) with the second electrode (640).

2. The junction according to claim 1, in which the first memristive matrix (605) is comprised of a first memristive material and the semiconductor matrix (615) is comprises of a second memristive material, the second memristive material being a different memristive material than the first memristive material.

3. The junction according to claim 1, further comprising a p-n junction (675) between the first memristive matrix (605) and the semiconductor matrix (685).

4. The junction according to claim 1, further comprising a transition layer (610) between the first memristive matrix (605) and the semiconductor matrix (615); the transition layer (610) comprising a mixture of the first memristive matrix (605) and the semiconductor matrix (615).

5. The junction of any of the above claims, in which the semiconductor matrix (615) has at least one of: a higher permittivity than the first memristive matrix (605) and a higher breakdown voltage than the first memristive matrix (605).

6. The junction of any of the above claims, in which a product of a permittivity and breakdown voltage of the semiconductor matrix (615) is greater than the product of a permittivity and breakdown voltage of the first memristive matrix (605).

7. The junction according to any of the above claims, further comprising mobile dopants (424) which are configured to be moved through the first memristive matrix (605) by the application of a programming voltage; the mobile dopant distribution being configured to define the programmable conductance of the electrical interface (625).

8. The junction according to any of the above claims, in which a concentration of the mobile dopants (424) within the first memristive matrix (605) adjacent to the first electrode (635) results in the electrical interface (625) having a conductive state; and depletion of the mobile dopants (424) within the first memristive matrix (605) adjacent to the first electrode (635) results in the electrical interface (625) having a less conductive state.

9. The junction according to any of the above claims, in which the switchable junction (600) is configured to form a switchable electrical connection between two nanowires (102, 104) in a crossbar array (200).

10. The junction according to any of the above claims, in which the first memristive matrix (605) and the semiconductor matrix (615) are compatible with the same mobile dopant species (424).

11. The junction according to any of the above claims, in which the first memristive matrix (605) comprises titanium dioxide and the semiconductor matrix (615) comprises strontium titanate.
